(19) United States
(12) Patent Application Publication
(10) Pub. No.: US 2018/0129016 A1
(43) Pub. Date: May 10, 2018

(54) METHOD FOR ACTIVATING AN ACTUATOR UNIT AND MICROMECHANICAL DEVICE

(71) Applicant: Robert Bosch GmbH, Stuttgart (DE)

(72) Inventor: Alexander Buhmann, Reutlingen (DE)

(21) Appl. No.: 15/803,056

(22) Filed: Nov. 3, 2017

(30) Foreign Application Priority Data
Nov. 9, 2016 (DE) 102016221966.9

(51) Int. Cl. G02B 7/198; B81B 3/00; G02B 26/08

(52) U.S. Cl. CPC G02B 7/198; F16D 2121/14; G02B 26/0833; B81B 3/004

(57) ABSTRACT

A method for activating a deflectable micromechanical actuator unit, in particular a micromirror. A periodic setpoint deflection profile of a deflection of the actuator unit is predefined at a predefined period duration. The actuator unit is periodically activated based on an activation signal according to the predefined period duration. A deflection profile of the deflection of the actuator unit is measured during at least one activation period. The activation signal is adapted for at least one of the following activation periods based on the setpoint deflection profile and on the measured deflection profile.

### CROSS REFERENCE

The present application claims the benefit under 35 U.S.C. § 119 of German Patent Application No. DE 102016221966.9 filed on Nov. 9, 2016, which is expressly incorporated herein by reference in its entirety.

### FIELD

The present invention relates to a method for activating a deflectable micromechanical actuator unit, in particular a micromirror, as well as a micromechanical device including a periodic drive.

### BACKGROUND INFORMATION

Micromirrors, which may be put into oscillation with the aid of electric or magnetic forces, are used in scanners, video projectors, and vehicle headlights. A deflectable micromirror of this type is German Patent Application No. DE 199 63 382 A1, for example.

Since the amplitude of the deflection is a function of external influences and therefore subject to change, the deflection of the micromirror must be controlled with high accuracy in order to ensure a precise deflection of the laser beam.

### SUMMARY

The present invention relates to a method for activating a deflectable micromechanical actuator unit and a micromechanical device including a periodic drive.

According to a first aspect, the present invention relates to a method for activating a deflectable micromechanical actuator unit, in particular a micromirror, a periodic setpoint deflection profile of a deflection of the actuator unit being predefined. The setpoint deflection profile includes a predefined period duration. The actuator unit is periodically activated based on an activation signal according to the predefined period duration, so that a period duration of the activation periods corresponds to the predefined period duration. A deflection profile of the deflection of the actuator unit is measured during at least one activation period. The activation signal is adapted for at least one of the following activation periods based on the setpoint deflection profile and based on the measured deflection profile.

The setpoint deflection profile corresponds to a predefined time curve of an amplitude of the deflection or of a swivel angle of the actuator unit.

According to another aspect, the present invention relates to a micromechanical device including a periodic drive which includes a deflectable actuator unit, a control unit, and a measuring device. The control unit is designed to periodically activate the actuator unit at a predefined period duration based on an activation signal. The measuring device is designed to measure a deflection profile of the deflection of the actuator unit during at least one activation period. The control unit is furthermore designed to adapt the activation signal for at least one of the following activation periods based on a periodic setpoint deflection profile and based on the measured deflection profile. A period duration of the setpoint deflection profile corresponds in this case to the predefined period duration.

Preferred specific embodiments are described herein.

Control concepts which continuously adapt the activation signal of the actuator unit even during the activation period have a great controller bandwidth, so that the latter may be greater than the first fundamental mode of the actuator unit and multiple interference modes of the actuator unit may exist within the controller bandwidth. As a result, a robust control is made more difficult, potentially giving rise to greater oscillations or unstable behavior. With the aid of the method according to the present invention, a controller is provided which itself is operated in an open mode during the activation period, so that the activation signal itself is not adapted during the activation period, but is left unchanged. The control and adaptation of the activation signal is carried out merely at the beginning of a new activation period or between two activation periods. This makes it possible to avoid the influence of interference modes and to improve the accuracy of the activation.

According to one preferred refinement of the method, the activation signal is adapted by using a fast block LMS algorithm, an LMS algorithm, an RLS algorithm, or a modification or a derived form of an algorithm of this type, in particular of a derived fast block LMS algorithm.

According to one refinement of the method, the activation signal is further adapted based on a property of the actuator unit, in particular on a resonance frequency of the actuator unit. In particular, a transfer function of an algorithm used for the adaptation may be determined as a function of the frequency and as a function of the resonance frequency of the actuator unit.

According to one preferred refinement of the method, the predefined period duration corresponds to a resonance frequency of the actuator unit. The predefined period duration is preferably equal to the inverse of the resonance frequency of the actuator unit.

According to one refinement of the method, the measuring of the deflection profile is repeated in each nth activation period, n being a positive natural number. The necessary computing power may be reduced by not measuring the deflection profile for each individual activation period.

According to another specific embodiment, the deflection profile may be measured across multiple activation periods. The deflection profile measured across multiple activation periods may be preferably averaged.

According to one preferred refinement of the method, the adapted activation signal may be used to activate the actuator unit starting with the mth subsequent activation period, m being a positive natural number. The activation period during which the actuator unit is activated based on the adapted activation signal does therefore not have to directly coincide with the measuring period, but may be separated from the latter by one or multiple activation periods. In particular, in the meantime the activation signal may be computed and adapted, so that slower and possibly more accurate algorithms may also be used.

According to one preferred refinement of the method, the actuator unit is deflectable in multiple deflection directions, the method being carried out separately for each of the directions of deflection.

According to one preferred refinement of the micromechanical device, the actuator unit includes a micromirror.

According to one refinement of the micromechanical device, the control unit is further designed to adapt the activation signal by using a fast block LMS algorithm or an LMS algorithm.

### BRIEF DESCRIPTION OF THE DRAWINGS

FIG. 1 shows a flow chart of a method for activating a deflectable micromechanical actuator unit according to one specific embodiment of the present invention;

FIG. 2 shows a schematic illustration of a setpoint deflection profile, a measured deflection profile, and an activation signal.

FIG. 3 shows a schematic view of a micromechanical device including a periodic drive according to one specific embodiment of the present invention.

### DETAILED DESCRIPTION OF EXAMPLE EMBODIMENTS

The numbering of the method steps is used for clarification purposes and is in general not supposed to imply a specific chronological sequence. In particular, several method steps may be carried out simultaneously. Various specific embodiments may be arbitrarily combined with one another, if expedient.

### DETAILED DESCRIPTION OF THE INVENTION

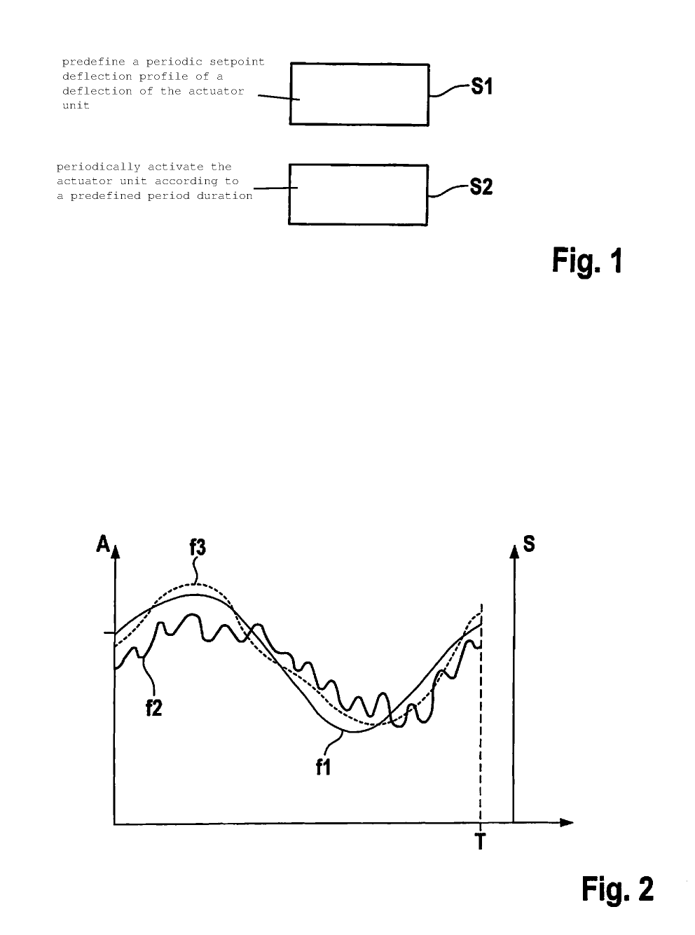

FIG. 1 shows a flow chart for elucidating a method for activating a deflectable micromechanical actuator unit. The actuator unit may in particular include at least one micromirror or a micromirror array. The actuator unit is deflectable, rotatable, or pivotable about one axis or two or multiple axes.

In a first method step S1, a periodic setpoint deflection profile of a deflection of the actuator unit is predefined. In FIG. 2, an exemplary setpoint deflection profile f1 of an amplitude A of the deflection of the actuator unit is illustrated, setpoint deflection profile f1 having a predefined period duration T. Predefined period duration T may preferably correspond to a resonance frequency of the actuator unit.

In another method step S2, the actuator unit is periodically activated based on an activation signal f2 according to predefined period duration T. A period duration of the activation signal and thus also every activation period is equal to predefined activation period T. An exemplary characteristic of a signal intensity S of activation signal f2 is also illustrated in FIG. 2.

A deflection profile f3 of the deflection of the actuator unit is measured during an activation period which is referred to as a measuring period in the following. An exemplary time curve of an amplitude A of measured deflection profile f3 is illustrated in FIG. 2. Corresponding measured values of the deflection of the actuator unit are preferably measured for a plurality of measuring points within the activation period, for example 512 measuring points, and deflection profile f3 is determined by interpolation.

For at least one of the activation periods following the measuring periods, activation signal f2 is adapted based on setpoint deflection profile f1 and measured deflection profile f3.

In the following, the adaptation of the activation signal is elucidated in greater detail with the aid of an algorithm which is derived from the fast block LMS algorithm. For this purpose, the values of deflection profile f3 which are measured during the measuring period at the measuring points in time are plotted as components in a measuring deflection vector. A setpoint deflection vector, whose components are equal to the values of setpoint deflection profile f1 at the particular measuring points in time, is similarly created. A Fourier-transformed measuring deflection vector and a Fourier-transformed setpoint deflection vector are determined by a Fourier transform of the measuring deflection vector or of the setpoint deflection vector. An error vector is computed with the aid of difference formation of the Fourier-transformed setpoint deflection vector and of the Fourier-transformed measuring deflection vector. The error vector is multiplied by a predefined scaling value and by a transfer function and an offset vector is computed therefrom. The transfer function may be selected as a function of frequency and may be determined, in particular, as a function of a property of the actuator unit, in particular of a resonance frequency of the actuator unit. The transfer function may, however, also be set to a constant value. According to another specific embodiment, corresponding offset vectors are computed for a phase as well as for an amplitude of the error vector. Activation signal f2 is also Fourier-transformed and a Fourier-transformed control signal vector having corresponding components is computed for each measuring point in time. The Fourier-transformed control signal vector is adapted through the addition of the offset vector and a new Fourier-transformed control signal vector is thus computed. The offset vector may also be weighted, in particular in order to adjust and improve the convergence and stability of the algorithm. Adapted activation signal f2 is determined with the aid of an inverse Fourier transform of the Fourier-transformed control signal vector and, potentially, by interpolation.

According to another specific embodiment, an LMS or an RLS algorithm may also be used to determine adapted activation signal f2.

According to one refinement of the method, the transfer function is determined via LMS algorithm in order to improve the convergence of the fast block LMS algorithm.

According to another specific embodiment, a wavelet decomposition may be used.

According to one specific embodiment, the actuator unit is activated based on the adapted activation signal during the activation period immediately following the measuring period. Deflection profile f3 of the deflection of actuator unit 2 is preferably measured during each individual activation period and activation signal f2 is adapted for the subsequent activation period.

The present invention is, however, not limited thereto. For example, the measuring of deflection profile f3 may also be carried out only for every nth activation period, n being a positive natural number. The deflection profile is measured for every second, third, or fourth activation period, for example. Accordingly, adapted activation signal f2 may be used to activate the actuator unit starting with the mth subsequent activation period, m being a positive natural number. For example, the deflection profile may be measured during a first activation period, the activation signal may be adapted during a subsequent second activation period, and the actuator unit is activated in an additional subsequent third activation period based on the adapted activation signal.

According to one refinement, the actuator unit is deflectable along several axes, a corresponding periodic setpoint deflection profile being predefined for each deflection and the activation signal being adapted according to the above-described method.

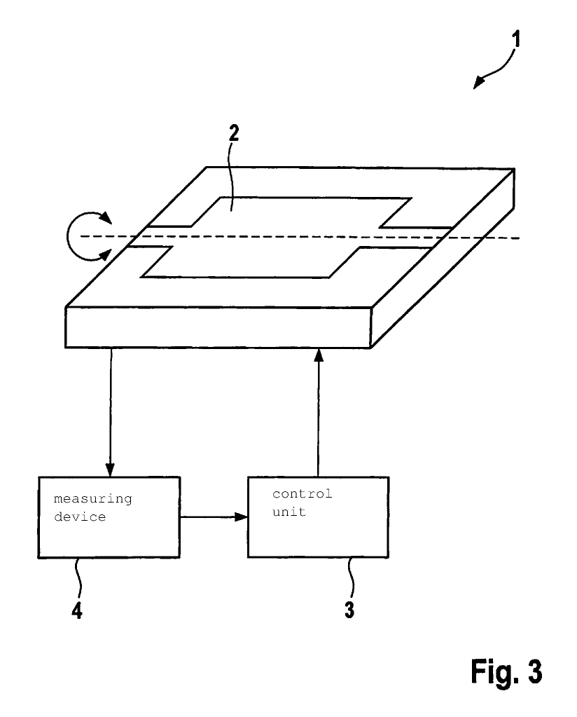

FIG. 3 shows a schematic view of a micromechanical device 1 including a periodic drive. Micromechanical device 1 includes a deflectable actuator unit 2, in particular a micromirror or a micromirror array, actuator unit 2 being rotatable, pivotable, or deflectable about one axis or multiple axes. Micromechanical device 1 further includes a control unit 3, and a measuring device 4. Control unit 3 is designed to periodically activate actuator unit 2 at a predefined period duration T based on an activation signal f2. Activation signal f2 may, for example, predefine a time curve of a voltage or of an electric current of an actuator for deflecting actuator unit 2.

Measuring device 4 is designed to measure a deflection profile f3 of the deflection of actuator unit 2 during at least one activation period.

Control unit 3 is furthermore designed to adapt activation signal f2 for at least one of the following activation periods based on a periodic setpoint deflection profile f1 and based on measured deflection profile f3. A period duration of setpoint deflection profile f1 corresponds in this case to predefined period duration T.

Control unit 3 may be designed, in particular, to adapt the activation signal by using a fast block LMS algorithm or an LMS algorithm, in particular according to the above-described method.

Control unit 3 may be designed to carry out each of the above-described methods.

What is claimed is:

1. A method for activating a deflectable micromechanical actuator unit, comprising:
predefining a periodic setpoint deflection profile of a deflection of the actuator unit at a predefined period duration; and
periodically activating the actuator unit based on an activation signal according to the predefined period duration;
measuring a deflection profile of the deflection of the actuator unit during at least one activation period; and
adapting the activation signal for at least one of the following activation periods based on the setpoint deflection profile and on the measured deflection profile.

2. The method as recited in claim 1, wherein the actuator unit is a micromirror.

3. The method as recited in claim 1, wherein the activation signal is adapted by using one of a fast block LMS algorithm, an LMS algorithm, or an RLS algorithm.

4. The method as recited in claim 1, wherein the activation signal is further adapted based on a property of the actuator unit, the property being a resonance frequency of the actuator unit.

5. The method as recited in claim 1, wherein the predefined period duration corresponds to a resonance frequency of the actuator unit.

6. The method as recited in claim 1, wherein the measuring of the deflection profile is repeated in every nth activation period, n being a positive natural number.

7. The method as recited in claim 1, wherein the adapted activation signal is used for activating the actuator unit starting with an mth subsequent activation period, m being a positive natural number.

8. The method as recited in claim 1, wherein the actuator unit is deflectable in multiple deflection directions and the method is carried out separately for every deflection direction.

9. A micromechanical device having a periodic drive, comprising:
a deflectable actuator unit;
a control unit designed to periodically activate the actuator unit at a predefined period duration based on an activation signal; and
a measuring device designed to measure a deflection profile of a deflection of the actuator unit during at least one activation period;
wherein the control unit is designed to adapt the activation signal for at least one of the following activation periods based on a periodic setpoint deflection profile and on the measured deflection profile, a period duration of the setpoint deflection profile corresponding to the predefined period duration.

10. The micromechanical device as recited in claim 9, wherein the actuator unit includes a micromirror.

11. The micromechanical device as recited in claim 9, wherein the control unit is designed to adapt the activation signal by using one of a fast block LMS algorithm, an LMS algorithm, or an RLS algorithm.
